(19) United States
(12) Patent Application Publication
(10) Pub. No.: US 2016/0035640 A1
(43) Pub. Date: Feb. 4, 2016

(54) UNDERFILL FILM, SEALING SHEET, METHOD OF MANUFACTURING SEMICONDUCTOR DEVICE, AND SEMICONDUCTOR DEVICE

(71) Applicant: NITTO DENKO CORPORATION, Osaka (JP)

(72) Inventors: Kosuke MORITA, Ibaraki-shi (JP); Naohide TAKAMOTO, Ibaraki-shi (JP); Hiroyuki HANAZONO, Ibaraki-shi (JP); Akihiro FUKUI, Ibaraki-shi (JP)

(21) Appl. No.: 14/782,289

(22) PCT Filed: Mar. 27, 2014
(86) PCT No.: PCT/JP2014/058849

§ 371 Date: Oct. 2, 2015

(30) Foreign Application Priority Data
Apr. 4, 2013 (JP) 2013-078907

(51) Int. Cl. H01L 23/31; C09J 7/02; H01L 21/56

(52) U.S. Cl. CPC H01L 23/3157; H01L 21/563; C09J 7/0207; C09J 2201/606

(57) ABSTRACT

The present invention provides an underfill film and a sealing sheet that are excellent in thermal conductive property and are capable of satisfactorily filling the space between the semiconductor element and the substrate. The present invention relates to an underfill film having a resin and a thermally conductive filler, in which a content of the thermally conductive filler is 50% by volume or more, an average particle size of the thermally conductive filler is 30% or less of a thickness of the underfill film, and a maximum particle size of the thermally conductive filler is 80% or less of the thickness of the underfill film.

### TECHNICAL FIELD

The present invention relates to an underfill film, a sealing sheet, a method of manufacturing a semiconductor device, and a semiconductor device.

### BACKGROUND ART

A method of installing a heat dissipating member such as a heat sink exists as a method of improving heat dissipation of a semiconductor package, etc.

For example, a technique is disclosed in Patent Document 1 of installing a heat dissipating member in a logic LSI to dissipate heat of the logic LSI. A technique is disclosed in Patent Document 2 of transferring heat that is generated in a driver chip to a heat dissipating metal foil to dissipate heat.

However, it is not desirable to install a heat dissipating member inside of a device having a limited casing size such as a digital camera or a cell phone. In addition, when the heat dissipating member is installed, not only does the cost of the heat dissipating member become necessary, but the number of the manufacturing processes also increases. Therefore, a problem occurs that the installation of the heat dissipating member leads to an increase in cost.

Because the connection reliability has to be ensured between a semiconductor element and a substrate in a flip-chip mounted semiconductor package, a space between the semiconductor element and the substrate is filled with an underfill material (sealing resin). A liquid-type underfill material has been broadly used as the underfill material (Patent Document 3).

### PRIOR ART DOCUMENTS

### Patent Documents

Patent Document 1: JP-A-2008-258306
Patent Document 2: JP-A-2008-275803
Patent Document 3: JP-A-2011-176278

### SUMMARY OF THE INVENTION

### Problems to be Solved by the Invention

A method of improving thermal conductive property of an underfill material can exist as a method of improving heat dissipation of the flip-chip mounted semiconductor package. However, when a large amount of filler is compounded in a liquid-type underfill material for improving the thermal conductive property, the viscosity of the underfill material increases and it may be difficult to fill a space between the semiconductor element and the substrate with the underfill material. For a small semiconductor package having a high density, the space may not be filled.

In Patent Document 3, an underfill composition having a low viscosity is disclosed that can be obtained by compounding divinylarene diepoxide in the underfill composition even when the filler is compounded at a high level. However, the thermal conductive property is not sufficient because silica is used. In addition, there is room for improvement in the filling property because the underfill composition is a liquid type.

The present invention takes into consideration the above-described problem points, and its purpose is to provide an underfill film and a sealing sheet that are excellent in thermal conductive property and capable of satisfactorily filling the space between the semiconductor element and the substrate.

### Means for Solving the Problems

The underfill film of the present invention contains a resin and a thermally conductive filler. The content of the thermally conductive filler is 50% by volume or more, the average particle size of the thermally conductive filler is 30% or less of the thickness of the underfill film, and the maximum particle size of the thermally conductive filler is 80% or less of the thickness of the underfill film.

In the underfill film of the present invention, the average particle size of the thermally conductive filler is set to 30% or less of the thickness of the underfill film, and the maximum particle size of the thermally conductive filler is set to 80% or less of the thickness of the underfill film. Therefore, the content of the thermally conductive filler can be set to a high value of 50% by volume or more. Because the underfill film can be packed with the thermally conductive filler at a relatively high density, an excellent thermal conductive property can be obtained. Because the average particle size and the maximum particle size of the thermally conductive filler to the thickness of the underfill film are optimized, the space between the semiconductor element and the substrate can be filled satisfactorily.

The thermal conductivity of the underfill film of the present invention is preferably 2 W/mK or more. If the thermal conductivity is 2 W/mK or more, the heat that is generated from the semiconductor element can be effectively dissipated to the outside.

The content of the thermally conductive filler is preferably 50 to 80% by volume, the average particle size of the thermally conductive filler is preferably 10 to 30% of the thickness of the underfill film, and the maximum particle size of the thermally conductive filler is preferably 40 to 80% of the thickness of the underfill film. The content and the form of the thermally conductive filler are set to the specific values, thereby to allow the heat dissipation of the underfill film to be improved well.

The arithmetic average roughness (Ra) of the underfill film of the present invention is preferably 300 nm or less. Since the thermally conductive filler having the specific content and the specific form is adopted, the arithmetic average roughness (Ra) can be 300 nm or less. If the arithmetic average roughness (Ra) is 300 nm or less, good adhering strength of the underfill film with the substrate and the semiconductor chip can be obtained.

The underfill film of the present invention preferably contains a thermally conductive filler having a different average particle size as the thermally conductive filler. With the underfill film containing a thermally conductive filler having a different average particle size it is possible to fill the space between thermally conductive fillers having a large average particle size with thermally conductive fillers having a small average particle size and to thereby improve the thermal conductive property.

The total light transmittance of the underfill film of the present invention is preferably 50% or more. If the total light transmittance is 50% or more, a position of the semiconductor element can be detected with high accuracy in the manufacturing method including a position matching step that is described later. Therefore, a dicing position can be easily determined. Further, the electrical connection between the semiconductor element and an adherend can be easily formed.

The present invention also relates to a sealing sheet having the underfill film and a pressure-sensitive adhesive tape, in which the pressure-sensitive adhesive tape has a base and a pressure-sensitive adhesive layer that is provided on the base and the underfill film is provided on the pressure-sensitive adhesive layer.

The peel strength of the underfill film from the pressure-sensitive adhesive layer is preferably 0.03 to 0.10 N/20 mm. This allows chip fly at dicing to be prevented.

The pressure-sensitive adhesive tape is preferably a tape for grinding the rear surface of a semiconductor wafer or a dicing tape.

The present invention also relates to a method of manufacturing a semiconductor device having an adherend, a semiconductor element that is electrically connected to the adherend, and an underfill film that fills the space between the adherend and the semiconductor element; and including a preparing step of preparing a semiconductor element with an underfill film in which the underfill film is bonded to the semiconductor element and a connecting step of electrically connecting the adherend and the semiconductor element while filling the space between the adherend and the semiconductor element with the underfill film.

The method of manufacturing a semiconductor device of the present invention preferably includes a position matching step of irradiating the exposed surface of the underfill film of the semiconductor element with an underfill film with oblique light, which is oblique with respect to the exposed surface, to match the relative positions of the semiconductor element and the adherend with the respective scheduled connection positions. This allows the positions of the semiconductor element and the adherend to be easily matched to the scheduled connection positions.

The exposed surface is preferably irradiated with the oblique light at an incident angle of 5 to 85°. If the exposed surface is irradiated with the oblique light at this incident angle, the generation of regular reflected light can be prevented thereby improving the position detection accuracy of the semiconductor element, and the accuracy of matching the positions to the scheduled connection positions.

The oblique light preferably contains a wavelength of 400 to 550 nm. If the oblique light contains the specified wavelength described above, good transmissivity of the oblique light is also exhibited to an underfill film material that is made from general materials including an inorganic filler. Therefore, the positions of the semiconductor element and the adherend can be easily matched to the scheduled connection positions.

The exposed surface of the underfill film is preferably irradiated with the oblique light from two or more directions or all directions. If the exposed surface is irradiated with oblique light from multiple directions or all directions (all circumferential directions), diffuse reflection from the semiconductor element is increased to improve the position detection accuracy, and the accuracy of matching the position of the semiconductor element to the scheduled connection position with the adherend can be further improved.

The present invention also relates to a semiconductor device that is manufactured by using the underfill film.

The present invention also relates to a semiconductor device that is manufactured with the method described above.

### BRIEF DESCRIPTION OF THE DRAWINGS

FIG. 1 is a schematic view of the cross section of a sealing sheet of the present invention.

FIGS. 2A to 2I are views showing each step of a method of manufacturing a semiconductor device of Embodiment 1.

FIG. 3 is a view showing a dicing position determination step of Embodiment 1.

FIG. 4 is a view showing a position matching step of Embodiment 1.

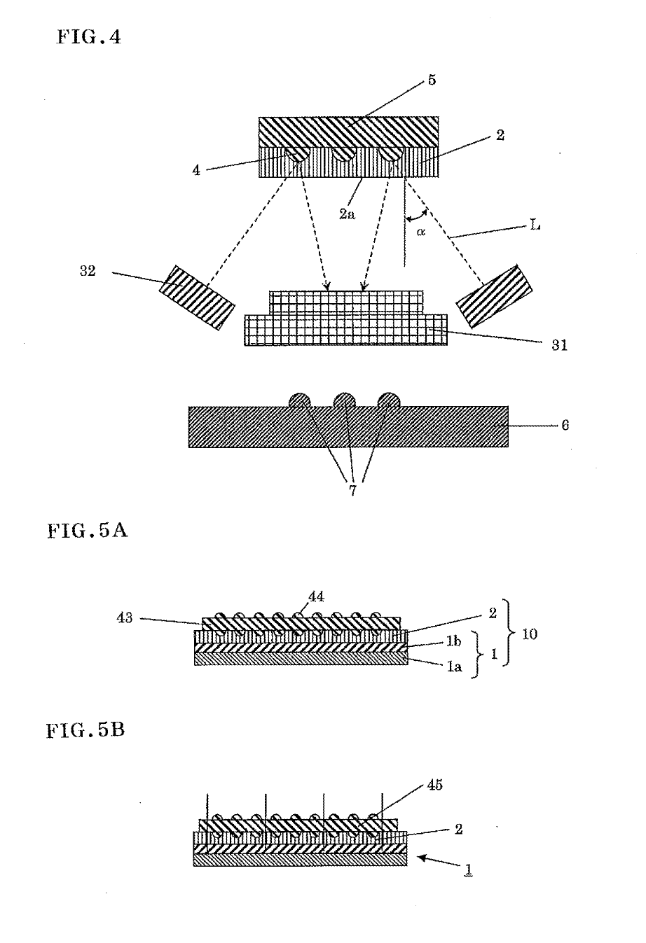

FIGS. 5A to 5E are views showing a method of manufacturing a semiconductor device of Embodiment 2.

### MODE FOR CARRYING OUT THE INVENTION

[Underfill Film]

The underfill film of the present invention contains a resin and a thermally conductive filler. The content of the thermally conductive filler is 50% by volume or more, the average particle size of the thermally conductive filler is 30% or less of the thickness of the underfill film, and the maximum particle size of the thermally conductive filler is 80% by volume of the thickness of the underfill film.

The underfill film of the present invention contains a thermally conductive filler.

The thermally conductive filler is not especially limited. However, examples are an electrically insulating compound such as aluminum oxide, zinc oxide, magnesium oxide, born nitride, magnesium hydroxide, aluminum nitride, and silicon carbide. These may be used either alone or in combination of two or more types. Among these, aluminum oxide is preferable in view of its high conductivity, excellent dispersibility, and ease of obtainability.

Although the thermal conductivity of the thermally conductive filler is not especially limited as long as a thermal conductive property can be given to the underfill film, the thermal conductivity is preferably 12 W/mK or more, more preferably 15 W/mK or more, and further preferably 25 W/mK or more. When the thermal conductivity is 12 W/mK or more, a thermal conductivity of 2 W/mK or more can be given to the underfill film.

The content of the thermally conductive filler in the underfill film is 50% by volume or more, and preferably 55% by volume or more. Because the content is 50% by volume or more, the thermal conductivity of the underfill film can be enhanced, and the heat that is generated in the semiconductor package can be dissipated efficiently. The content of the thermally conductive filler in the underfill film is 80% by volume or less, and preferably 75% by volume or less. When the content is 80% by volume or less, the adhesion component in the underfill film can be prevented from relatively decreasing, and the wettability and the adhesion of the underfill film to a semiconductor element, etc., can be ensured.

The average particle size of the thermally conductive filler to the thickness of the underfill film is 30% or less, preferably 25% or less, more preferably 5% or less, and especially preferably 4% or less. When the average particle size exceeds 30%, the ability of the underfill film to act as a filler may be inadequate relative to the amount of unevenness at the substrate and the semiconductor element, and the inadequate filling ability may cause generation of voids. The lower limit of the average particle size is not especially limited. However, the lower limit of the average particle size to the thickness of the underfill film is preferably 0.5% or more, and more preferably 1% or more.

The maximum particle size of the thermally conductive filler to the thickness of the underfill film is 80% or less, preferably 70% or less, more preferably 40% or less, and further preferably 15% or less. When the maximum particle size exceeds 80%, the ability of the underfill film to act as a filler to fill unevenness at the substrate and the semiconductor element may decrease, and voids may occur between the connection terminals to cause a bonding failure. The lower limit of the maximum particle size is not especially limited. However, the lower limit of the maximum particle size to the thickness of the underfill film is preferably 1% or more, and more preferably 5% or more. The maximum particle size of the thermally conductive filler means the largest particle size in all thermally conductive fillers that are contained in the underfill film.

The average particle size and the maximum particle size of the thermally conductive filler are values that are obtained by a laser diffraction particle size analyzer (trade name “LA-910” manufactured by HORIBA, Ltd.)

The underfill film of the present invention preferably contains a thermally conductive filler having a different average particle size. With this, the space between thermally conductive fillers having a large average particle size can be filled with the thermally conductive fillers having a small average particle size to enhance the thermal conductive property.

The average particle size of the thermally conductive filler having a small average particle size is preferably 1 to 50% to the average particle size of the thermally conductive filler having a large average particle size. When the average particle size of the thermally conductive filler having a small average particle size is within the above-described range, the thermal conductive property can be enhanced further.

The particle shape of the thermally conductive filler is not especially limited. However, examples include a spherical shape, an oval-spherical shape, a flat shape, a needle-like shape, a fiber-like shape, a flake shape, a spike-like shape, and a coil-like shape. Among these shapes, the spherical shape is preferable in view of its excellent dispersibility and capability of improving the filling rate.

The underfill film of the present invention contains a resin. The resin is not especially limited. However, examples include an acrylic resin and a thermosetting resin. The acrylic resin and the thermosetting resin are preferably used together.

The acrylic resin is not particularly limited, and examples thereof include polymers having as a component one or more of esters of acrylic acids or methacrylic acids which have a linear or branched alkyl group having 30 or fewer of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and an dodecyl group.

Other monomers for forming the polymer are not particularly limited, and examples thereof include cyano group-containing momomers such as acrylonitrile, carboxyl group-containing monomers such as acrylic acid, methacrylic acid, carboxyethyl acrylate, carboxypentyl acrylate, itaconic acid, maleic acid, fumaric acid and crotonic acid, acid anhydride monomers such as maleic anhydride and itaconic anhydride, hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate and (meth)acryloyloxynaphthalenesulfonic acid, and phosphoric acid group-containing monomers such as 2-hydroxyethylacryloyl phosphate.

The content of the acrylic resin in the underfill film is preferably 2% by weight or more, and more preferably 5% by weight or more. When the content is 2% by weight or more, the sheet has flexibility, and the handling property of the film can be improved. The content of the acrylic resin in the underfill film is preferably 30% by weight or less, and more preferably 25% by weight or less. When the content is 30% by weight or less, a sufficient filling property can be obtained against to the unevenness of the substrate and the semiconductor element.

Examples of the thermosetting resin include a phenol resin, an amino resin, an unsaturated polyester resin, an epoxy resin, a polyurethane resin, a silicone resin, and a thermosetting polyimide resin. These resins may be used either alone or in combination of two or more thereof. Especially, an epoxy resin is preferable, in view of having a small amount of ionic impurities and the like that corrode the semiconductor element, the flow-out of adhesive of the underfill film can be suppressed at the cut surface of dicing, and the reattaching (blocking) of the cut surfaces can be suppressed. A phenol resin is preferable as a curing agent for the epoxy resin.

The epoxy resin is not particularly limited as long as it is generally used as an adhesive composition, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type, or a tetraphenylol ethane type, or an epoxy resin such as a hydantoin type, a trisglycidyl isocyanurate type, or a glycidyl amine type is used. They can be used alone, or in combination of two or more thereof. Among these epoxy resins, a novolak type epoxy resin, a biphenyl type epoxy resin, a trishydroxyphenyl methane type resin, or a tetraphenylol ethane type epoxy resin is especially preferable. This is because the aforementioned resins have a high reactivity with a phenol resin as a curing agent, and are excellent in heat resistance and so on.

Further, the phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, resole type phenol resins, and polyoxystyrenes such as polyparaoxystyrene. They can be used alone, or in combination of two or more thereof. Among these phenol resins, a phenol novolak resin and a phenol aralkyl resin are especially preferable. This is because the connection reliability of a semiconductor device can be improved therewith.

The compounding ratio of the phenol resin to the epoxy resin is preferably set so that the hydroxy group in the phenol resin is 0.5 to 2.0 equivalents per one equivalent of the epoxy group in the epoxy resin component. The hydroxy group in the phenol resin is more preferably 0.8 to 1.2 equivalents. If it is outside of this range, the curing reaction does not proceed sufficiently, and the characteristics of the underfill film can easily deteriorate.

The content of the thermosetting resin in the underfill film is preferably 5% by weight or more, and more preferably 10% by weight or more. When the content is 5% by weight or more, the thermal characteristics of the underfill film after curing improves and the reliability can be easily maintained. The content of the thermosetting resin in the underfill film is preferably 80% by weight or less, more preferably 50% by weight or less, and further preferably 30% by weight or less. When the content is 80% by weight or less, the reliability can be easily maintained.

The thermal cure promoting catalyst of the epoxy resin and the phenol resin is not especially limited, and can be appropriately selected from the known thermal cure promoting catalysts. The thermal cure promoting catalyst may be used either alone or in combination of two or more types. Examples of the thermal cure promoting catalyst include an amine curing accelerator, a phosphorous curing accelerator, an imidazole curing accelerator, a boron curing accelerator, and a phosphor-boron curing accelerator.

The content of the thermal cure promoting catalyst is preferably 0.01 parts by weight or more, and more preferably 0.1 parts by weight or more to the total 100 parts by weight of the epoxy resin and the phenol resin. When the content of the thermal cure promoting catalyst is 0.01 parts by weight or more, the curing time by heat processing becomes small to improve the productivity. The content of the thermal cure promoting catalyst is preferably 5 parts by weight or less, and more preferably 2 parts by weight or less. When the content of the thermal cure promoting catalyst is 5 parts by weight or less, the storage property of the thermosetting resin can be improved.

A flux may be added to the underfill film for easily mounting the semiconductor element. The oxide film on the surface of the solder bump can be removed by adding the flux to the underfill film. The flux is not especially limited, and a conventionally known compound having a flux effect can be used. Examples of the flux include ortho-anisic acid, diphenolic acid, adipic acid, acetylsalicylic acid, benzoic acid, benzilic acid, azelaic acid, benzylbenzoic acid, malonic acid, 2,2-bis(hydroxymethyl) propionic acid, salicylic acid, o-methoxybenzoic acid, m-hydroxybenzoic acid, succinic acid, 2,6-dimethoxymethylparacresol, benzoic acid hydrazide, carbohydrazide, malonic acid dihydrazide, succinic acid dihydrazide, glutaric acid dihydrazide, salicylic acid hydrazide, iminodiacetic acid dihydrazide, itaconic acid dihydrazide, citric acid trihydrazide, thiocarbohydrazide, benzophenone hydrazone, 4,4′-oxybisbenzene sulfonylhyrazide, and azipic acid dihydrazide. The flux may be added at an amount that is necessary for the flux effect, and the amount of the flux is normally about 0.1 parts by weight to 20 parts by weight to 100 parts by weight of the resin component (the resin component such as the acrylic resin and the thermosetting resin) in the underfill film.

The underfill film may be colored as necessary. The color that is given by coloring of the underfill film is not especially limited. However, black, blue, red, green, etc., are preferable. A coloring agent can be used that is appropriately selected from the known coloring agents such as a pigment and a dye.

When the underfill film is cross-linked to a certain extent in advance, a multifunctional compound may be added that reacts with a functional group, etc., at the ends of the polymer molecular chain as a cross-linking agent in the production of the underfill film.

In particular, a polyisocyanate compound is more preferable as the cross-linking agent such as tolylene diisocyanate, diphenylmethane diisocyanate, p-phenylene diisocyanate, 1,5-naphthalene diisocyanate, and an adduct of polyhydric alcohol and diisocyanate.

Other additives besides the above-described components can be appropriately compounded in the underfill film. Examples of other additives include a flame retardant, a silane coupling agent, and an ion trapping agent. Examples of the flame retardant include antimony trioxide, antimony pentoxide, and a brominated epoxy resin. These may be used either alone or in combination of two or more types. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds may be used either alone or in combination of two or more types. Examples of the ion trapping agent include hydrotalcites and bismuth hydroxide. These may be used either alone or in combination of two or more types.

For example, the underfill film can be produced as follows. First, each of the components described above that are the forming materials of the underfill film is compounded, and it is dissolved or dispersed in a solvent (for example, methylethylketone, ethyl acetate, etc.) to prepare a coating liquid. Next, the prepared coating liquid is applied on a base separator to form a coating film having a prescribed thickness. Then, the coating film is dried to form an underfill film.

The thermal conductivity of the underfill film of the present invention is normally 2 W/mK or more, preferably 3 W/mK or more, and more preferably 5 W/mK or more. If the thermal conductivity is 2 W/mK or more, the heat that is generated in the semiconductor package can be dissipated efficiently. The upper limit of the thermal conductivity is not especially limited, and for example, 70 W/mK or less.

The arithmetic average roughness (Ra) of the underfill film of the present invention before thermal curing is preferably 300 nm or less, and more preferably 250 nm or less. If the arithmetic average roughness (Ra) is 300 nm or less, good wettability of the underfill film to a substrate and a semiconductor element, etc., can be obtained. The lower limit of the arithmetic average roughness (Ra) is not especially limited, and for example, 10 nm or more.

The arithmetic average roughness (Ra) can be measured using a non-contact three-dimensional profilometer (NT3300) manufactured by Veeco Instruments, Inc. based on JIS B 0601. Specifically, the measurement condition is set to 50 magnifications, and a median filter is used to the measured data to obtain a measurement value.

The thickness of the underfill film of the present invention may be appropriately set in consideration of the gap between the semiconductor element and the adherend and the height of the connection member. For example, the thickness is preferably 10 μm or more, and more preferably 15 μm or more. The thickness is preferably 100 μm or less, and more preferably 50 μm or less.

The underfill film of the present invention is preferably protected by a separator. The separator has a function as a protecting material to protect the underfill film before use. The separator is peeled off when the semiconductor element is bonded onto the underfill film. Polyethylene terephthalate (PET), polyethylene, polypropylene, a plastic film, and a paper sheet in which its surface is coated with a peeling agent such as a fluorine peeling agent or a long-chain alkylacrylate peeling agent can be also used as a separator.

A higher total light transmittance of the underfill film of the present invention is more preferable. Specifically, the total light transmittance is preferably 50% or more, more preferably 60% or more, and still more preferably 70% or more. If the manufacturing method includes a position matching step that is described later, the position of the semiconductor element can be detected with high accuracy even when the total light transmittance is about 50%. Therefore, the dicing position can be easily determined. Further, the electrical connection between the semiconductor element and an adherend can be easily formed.

The total light transmittance can be measured using a hazemeter HM-150 (manufactured by MIRAKAMI COLOR RESEARCH LABORATORY CO., Ltd.) according to JIS K 7361.

The underfill film of the present invention can be used as a sealing film to fill the space between the semiconductor element and the adherend. Examples of the adherend include a circuit board, a flexible board, an interposer, a semiconductor wafer, and a semiconductor element, etc.

The underfill film of the present invention can be integrated with a pressure-sensitive adhesive tape. This makes it possible to effectively manufacture the semiconductor device.

[Sealing Sheet (Underfill Film Integrated with Pressure-Sensitive Adhesive Sheet)]

The sealing sheet of the present invention has the underfill film and a pressure-sensitive adhesive tape.

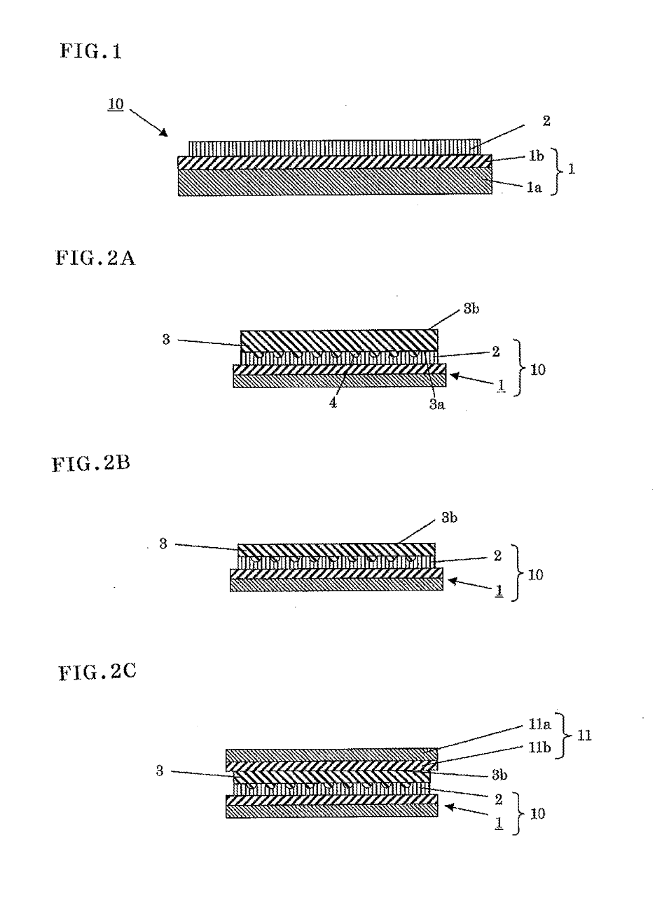

FIG. 1 is a schematic view of the cross section of a sealing sheet 10 of the present invention. As shown in FIG. 1, the sealing sheet 10 has an underfill film 2 and a pressure-sensitive adhesive tape 1. The pressure-sensitive adhesive tape 1 has a base 1a and a pressure-sensitive adhesive layer 1b, and the pressure-sensitive adhesive layer 1b is provided on the base 1a. The underfill film 2 is provided on the pressure-sensitive adhesive layer 1b.

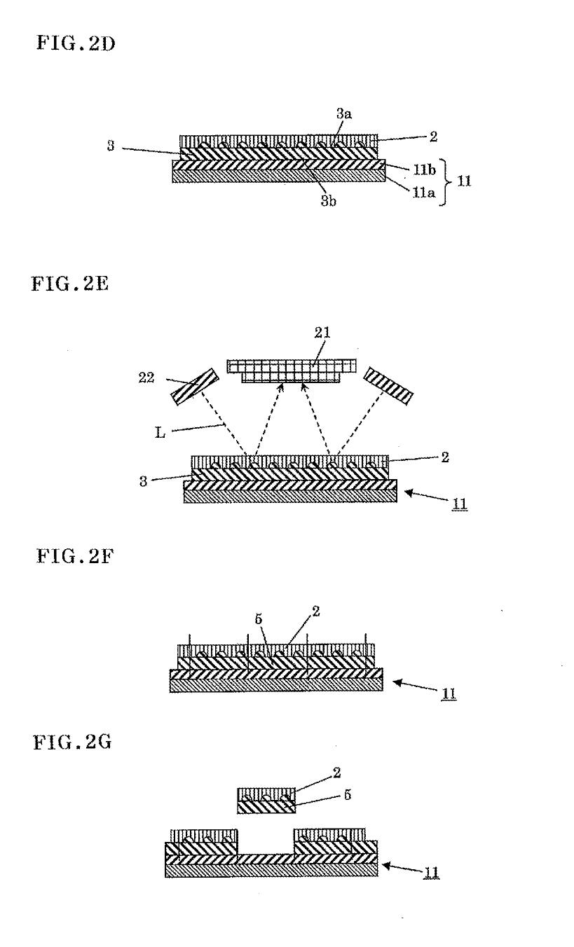

The underfill film 2 is not necessarily provided on the entire surface of the pressure-sensitive adhesive tape 1 as shown in FIG. 1, and the underfill film 2 may be provided, with a size that is sufficient for bonding to a semiconductor wafer 3 (refer to FIG. 2A).

The pressure-sensitive adhesive tape 1 has the base 1a and the pressure-sensitive adhesive layer 1b that is laminated on the base 1a.

The base 1a becomes abase material for strength of the sealing sheet 10. Examples include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene, and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper. When the pressure-sensitive adhesive layer 1b is of an ultraviolet-ray curing type, the base 1a is preferably one having a permeability to ultraviolet rays.

A common surface treatment can be performed on the surface of the base 1a.

For the base 1a, the same material or different materials can be appropriately selected and used, and one obtained by blending several materials can be used as necessary. The base 1a can be provided thereon with a vapor-deposited layer of an electrically conductive substance made of a metal, an alloy, an oxide thereof, or the like and having a thickness of about 30 to 500 Å for imparting an antistatic property. The base 1a may be a single layer or a multiple layer having two or more layers.

The thickness of the base 1a is not particularly limited, and can be appropriately determined, but is generally about 5 to 200 μm, and is preferably 35 to 120 μm.

The base 1a may contain various kinds of additives (e.g. colorant, filler, plasticizer, antiaging agent, antioxidant, surfactant, flame retardant, etc.) within the bounds of not impairing the effect of the present invention.

The pressure-sensitive adhesive that is used to form the pressure-sensitive adhesive layer 1b is not especially limited, and for example, a general pressure-sensitive adhesive can be used such as an acrylic pressure-sensitive adhesive and a rubber pressure-sensitive adhesive. The pressure-sensitive adhesive is preferably an acrylic pressure-sensitive adhesive having an acrylic polymer as a base polymer from the viewpoint of its capability of being washed and cleaned well with ultrapure water or an organic solvent such as alcohol.

Examples of the acryl-based polymer include those using an acrylate as a main monomer component. Examples of the acrylate include one or more of (meth)acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nony ester, decyl ester, isodecyl ester, undecyl ester, dodecyl ester, tridecyl ester, tetradecyl ester, hexadecyl ester, octadecyl ester and eicosyl ester), and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth)acrylic acid alkyl ester or cycloalkyl ester as necessary for the purpose of modifying cohesive strength, heat resistance and so on. Examples of the monomer component include carboxyl group-containing monomers such as acrylic acid, methacrylic acid, carboxyethyl (meth)acrylate, carboxypentyl (meth)acrylate, itaconic acid, maleic acid, fumaric acid and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methyl (meth)acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of cross-linking. Examples of the polyfunctional monomer include hexanediol di(meth)acrylate, (poly)ethylene glycol di(meth)acrylate, (poly)propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy (meth)acrylate, polyester (meth)acrylate, and urethane (meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization, or suspension polymerization. The content of low-molecular weight substances is preferably low from the viewpoint of prevention of contamination of a clean adherend. In this respect, the number average molecular weight of the acryl-based polymer is preferably 300,000 or more, further preferably about 400,000 to 3,000,000.

For the pressure-sensitive adhesive, an external cross-linker can also be appropriately employed for increasing the number average molecular weight of an acryl-based polymer or the like as a base polymer. Specific examples of the external cross-linking methods include a method in which so called a cross-linker such as a polyisocyanate compound, an epoxy compound, an aziridine compound, or a melamine-based cross-linker is added and reacted. When an external cross-linker is used, the used amount thereof is appropriately determined according to a balance with a base polymer to be cross-linked, and further a use application as a pressure-sensitive adhesive. Generally, the external cross-linker is blended in an amount of preferably about 5 parts by weight or less, further preferably 0.1 to 5 parts by weight, based on 100 parts by weight of the base polymer. Further, for the pressure-sensitive adhesive, various previously known kinds of additives, such as a tackifier and an anti-aging agent, may be used as necessary in addition to the aforementioned components.

The pressure-sensitive adhesive layer 1b can be formed by radiation curing-type pressure-sensitive adhesive. By irradiating the radiation curing-type pressure-sensitive adhesive with radiations such as ultraviolet rays, the degree of cross-linking thereof can be increased to easily reduce its adhesive power. Examples of radiations include X-rays, ultraviolet rays, electron rays, α rays, β rays, and neutron rays.

For the radiation curing-type pressure-sensitive adhesive, one having a radiation-curable functional group such as a carbon-carbon double bond and showing adherability can be used without particular limitation. Examples of the radiation curing-type pressure-sensitive adhesive may include, for example, an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane (meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta(meth)acrylate, dipentaerythrithol hexa(meth)acrylate and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30,000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curing-type pressure-sensitive adhesive include, besides the addition-type radiation curing-type pressure-sensitive adhesive described previously, an intrinsic radiation curing-type pressure-sensitive adhesive using, as a base polymer, a polymer having a carbon-carbon double bond in the polymer side chain or main chain or at the end of the main chain. The intrinsic radiation curing-type pressure-sensitive adhesive is preferable because it is not required to contain, or mostly does not contain, an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used with no particular limitation. Such abase polymer is preferably one having an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group, and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethyl vinyl ether, 4-hydroxybutyl vinyl ether and diethylene glycol monovinyl ether, and so on is used.

For the intrinsic radiation curing-type pressure-sensitive adhesive, the base polymer (particularly acryl-based polymer) having a carbon-carbon double bond can be used alone, but the radiation curable monomer component or oligomer component within the bounds of not deteriorating properties can also be blended. The amount of the radiation curable oligomer component or the like is normally within a range of 30 parts by weight or less, preferably in a range of 0 to 10 parts by weight, based on 100 parts by weight of the base polymer.

A photopolymerization initiator is preferably included in the radiation curing-type pressure-sensitive adhesive when it is cured by ultraviolet rays or the like. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether and anisoin methyl ether; ketal-based compounds such as benzyldimethylketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds such as benzophenone, benzoyl benzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

When curing hindrance by oxygen occurs at the time of the irradiation of radiations, it is desirable to block oxygen (air) from the surface of the radiation curing-type pressure-sensitive adhesive layer 1b by some method. Examples include a method in which the surface of the pressure-sensitive adhesive layer 1b is covered with a separator, and a method in which irradiation of radiations such as ultraviolet rays or the like is carried out in a nitrogen gas atmosphere.

The pressure-sensitive adhesive layer 1b may contain various types of additives (such as a coloring agent, a thickener, an extender, a filler, a tackifier, a plasticizer, an antiaging agent, an antioxidant, a surfactant, and a cross-linking agent).

The thickness of the pressure-sensitive adhesive layer 1b is not especially limited, and for example, about 1 to 50 μm, preferably 2 to 30 μm, and more preferably 5 to 25 μm.

A tape for grinding the rear surface of a semiconductor wafer or a dicing tape can be suitably used as the pressure-sensitive adhesive tape 1.

For example, the pressure-sensitive adhesive tape 1 and the underfill film 2 may be produced separately and bonded together at the end to produce the sealing sheet 10.

The peel strength of the underfill film 2 from the pressure-sensitive adhesive layer 1b in the sealing sheet 10 is preferably 0.03 to 0.10 N/20 mm. When the peel strength is 0.03 N/20 mm or more, chip fly at dicing can be prevented. When the peel strength is 0.10 N/20 mm or less, a good pickup property can be obtained.

[Method of Manufacturing Semiconductor Device]

In the method of manufacturing a semiconductor device of the present invention, a semiconductor device is manufactured that has an adherend, a semiconductor element that is electrically connected to the adherend, and an underfill film that fills the space between the adherend and the semiconductor element.

The method of manufacturing a semiconductor device of the present invention includes a preparation step of preparing a semiconductor element with an underfill film in which the underfill film is bonded to the semiconductor element and a connection step of electrically connecting the adherend and the semiconductor element while filling the space between the adherend and the semiconductor element with the underfill film.

The method of manufacturing a semiconductor device of the present invention is not especially limited as long as a preparation step and a connection step are included therein; however, it preferably includes a position matching step of irradiating the exposed surface of the underfill film of the semiconductor element with an underfill film with oblique light to match the relative positions of the semiconductor element and the adherend with the scheduled connection positions. This makes it possible to easily match the positions of the semiconductor element and the adherend with the scheduled connection positions.

The method of manufacturing a semiconductor device of the present invention will be explained in detail below by using the embodiments. However, the method of manufacturing a semiconductor device of the present invention is not limited to these embodiments.

### Embodiment 1

The method of manufacturing a semiconductor device of Embodiment 1 is explained. FIGS. 2A to 2I are views showing each step of the method of manufacturing a semiconductor device of Embodiment 1.

The sealing sheet 10 is used in Embodiment 1.

The method of manufacturing a semiconductor device of Embodiment 1 includes a bonding step of bonding a circuit surface 3a on which a connection members 4 of the semiconductor wafer 3 are formed and the underfill film 2 of the sealing sheet 10 together, a grinding step of grinding a rear surface 3b of the semiconductor wafer 3, a wafer fixing step of bonding a dicing tape 11 to the rear surface 3b of the semiconductor wafer 3, a peeling step of peeling the pressure-sensitive adhesive tape 1, a dicing position determination step of irradiating the exposed surface of the underfill film 2 of the semiconductor wafer 3 with the underfill film 2 with oblique light L to determine a dicing position, a dicing step of dicing the semiconductor wafer 3 to form a semiconductor element 5 with the underfill film 2, and a pickup step of peeling the semiconductor element 5 with the underfill film 2 from the dicing tape 11, a position matching step of irradiating the exposed surface of the underfill film 2 of the semiconductor element 5 with the underfill film 2 with the oblique light L to match the relative positions of the semiconductor element 5 and the adherend 6 with the scheduled connection positions, a connection step of electrically connecting the adherend 6 and the semiconductor element 5 with the underfill film 2 while filling the space between the adherend 6 and the semiconductor element 5 with the underfill film 2 of the semiconductor element 5 with the underfill film 2.

<Bonding Step>

In the bonding step, the circuit surface 3a of the semiconductor wafer 3 on which the connection members 4 are formed and the underfill film 2 of the sealing sheet 10 are bonded together (refer to FIG. 2A).

A plurality of the connection members 4 are formed on the circuit surface 3a of the semiconductor wafer 3 (refer to FIG. 2A). The material of the connection member 4 is not especially limited, and examples of the material include solders (alloys) such as tin-lead metal, tin-silver metal, tin-silver-copper metal, tin-zinc metal, and tin-zinc-bismuth metal; gold metal; and copper metal. The height of the connection member 4 is determined depending on its use, and it is generally about 15 μm to 100 μm. Naturally, the height of each connection member 4 in the semiconductor wafer 3 may be the same or different from each other.

First, a separator is appropriately peeled that is arbitrarily provided on the underfill film 2 of the sealing sheet 10, and the circuit surface 3a on which the connection members 4 of the semiconductor wafer 3 are formed is arranged to face the underfill film 2 as shown in FIG. 2A, so that the underfill film 2 and the semiconductor wafer 3 are bonded together (mounting).

The method of the bonding is not especially limited; however, a method of press-bonding is preferable. The pressure of press-bonding is preferably 0.1 MPa or more, and more preferably 0.2 MPa or more. If the pressure is 0.1 MPa or more, the unevenness of the circuit surface 3a of the semiconductor wafer 3 can be suitably filled. The upper limit of the pressure of press-bonding is not especially limited; however, it is preferably 1 MPa or less, and more preferably 0.5 MPa or less.

The temperature at the bonding is preferably 60° C. or higher, and more preferably 70° C. or higher. If the temperature is 60° C. or higher, the viscosity of the underfill film 2 decreases, and the unevenness of the semiconductor wafer 3 can be filled with the underfill film 2 without any gap. The temperature at the bonding is preferably 100° C. or lower, and more preferably 80° C. or lower. If the temperature is 100° C. or lower, the bonding can be performed while suppressing the curing reaction of the underfill film 2.

The bonding is preferably performed under reduced pressure, for example, 1,000 Pa or less, and preferably 500 Pa or less. The lower limit is not especially limited, and for example, 1 Pa or more.

<Grinding Step>

In the grinding step, the surface opposite to the circuit surface 3a of the semiconductor wafer 3 (i.e., the rear surface 3b) is grinded (refer to FIG. 2B). A thin-type processing apparatus that is used in grinding the rear surface of the semiconductor wafer 3 is not especially limited, and therefore may, for example, include a grinding apparatus (back grinder) and a polishing pad. The rear surface may be grinded with a chemical method such as etching. The rear surface is grinded until the thickness of the semiconductor wafer 3 reaches a desired thickness (for example, 700 μm to 25 μm).

<Wafer Fixing Step>

After the grinding step, the dicing tape 11 is bonded to the rear surface 3b of the semiconductor wafer 3 (refer to FIG. 2C). The dicing tape 11 has a structure in which a pressure-sensitive adhesive layer 11b is laminated on a base 11a. The base 11a and the pressure-sensitive adhesive layer 11b can be suitably produced using the components and the manufacturing method shown in the section of the base 1a and the pressure-sensitive adhesive layer 1b of the pressure-sensitive adhesive tape 1.

<Peeling Step>

Next, the pressure-sensitive adhesive tape 1 is peeled (refer to FIG. 2D). This allows the underfill film 2 to be exposed.

When the tape 1 for grinding the rear surface is peeled and the pressure-sensitive adhesive layer 1b is radiation-curable, the pressure-sensitive adhesive layer 1b is cured by irradiating the pressure-sensitive adhesive layer 1b with radiation to easily peel the tape 1 for grinding the rear surface. The amount of radiation may be appropriately set in consideration of the type of radiation to be used, the degree of curing of the pressure-sensitive adhesive layer, etc.

<Dicing Position Determination Step>

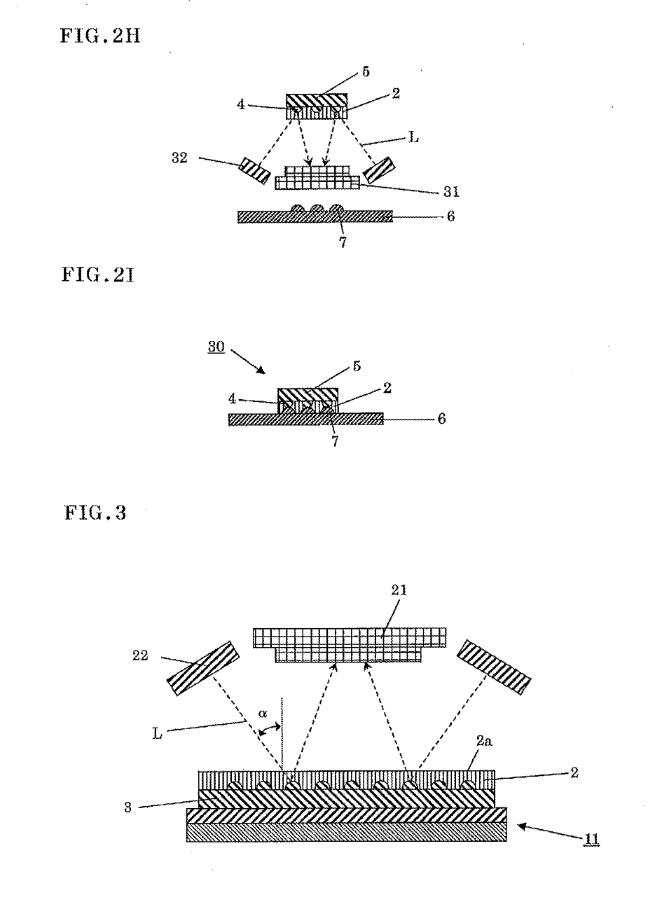

As shown in FIGS. 2E and 3, the exposed surface of the underfill film 2 of the semiconductor wafer 3 with the underfill film 2 is irradiated with the oblique light L to determine the dicing position in the semiconductor wafer 3. This allows the dicing position of the semiconductor wafer 3 to be detected at high accuracy, and the dicing of the semiconductor wafer 3 to be simply and effectively performed.

Specifically, an imaging apparatus 21 and a ring lighting (lighting having a circular light-emitting surface) 22 are arranged above the semiconductor wafer 3 that is fixed to the dicing tape 11. Next, the exposed surface 2a of the underfill film 2 is irradiated with the oblique light L from the ring lighting 22 at a prescribed incident angle α. The light that enters into the underfill film 2 and reflects at the semiconductor wafer 3 is received as a reflected image in the imaging apparatus 21. The received reflected image is analyzed using an image recognition apparatus to determine the position that has to be diced. After that, the dicing apparatus (for example, a dicing blade, a laser generator, etc.) is moved and matched with the dicing position to complete the present step (not shown in the figures).

The ring lighting 22 can be suitably used as the lighting for the oblique light radiation. However, the lighting is not especially limited to the ring lighting 22, and a line lighting (lighting having a linear light-emitting surface), a spot lighting (lighting having spot-like light emitting surfaces), etc., can be used. The lighting may be a lighting in which a plurality of the line lightings are combined in a polygonal shape or a lighting in which the spot lightings are combined in a polygonal shape or a ring.

The source of the lighting is not especially limited, and examples of the source include a halogen lamp, an LED, a fluorescent lamp, a tungsten lamp, a metal halide lamp, a xenon lamp, and a black light. The oblique light L that is radiated from the source may be any of parallel rays and radiant rays (non-parallel rays); however, it is preferably parallel rays in consideration of the radiation efficiency and the easiness of setting the incident angle α. However, there is a physical limitation to radiate the oblique light L as parallel rays. Therefore, the oblique light L may be practically parallel rays (the half-value angle is within 30°). The oblique light L may be polarized light.

In the present embodiment, the exposed surface 2a of the underfill film 2 is irradiated with the oblique light L from two or more directions or all directions. The irradiation with oblique light from multiple directions or all directions allows the diffuse reflection from the semiconductor wafer 3 to increase and thereby to improve the position detection accuracy, and the accuracy of detecting the dicing position can be further improved. One of the line lighting and the spot lighting, a combination of both, etc., can be used to perform the irradiation from multiple directions. A plurality of the line lightings may be combined in the form of a polygonal shape or the ring lighting can be used to easily perform the irradiation from all directions or all circumferential directions.

The incident angle α is not especially limited as long as the exposed surface 2a of the underfill film 2 is irradiated with the oblique light L in such a manner that the rays of the light L is inclined to the exposed surface 2a; however, it is preferably 5 to 85°, more preferably 15 to 75°, and especially preferably 30 to 60°. When the incident angle α falls within this range, the generation of regular reflected light from the semiconductor wafer 3, which causes a halation phenomenon, can be prevented to improve the accuracy of detecting the dicing position of the semiconductor wafer 3. If the oblique light L is radiant rays (non-parallel rays), a difference in the incident angle α may occur to some extent depending on the relationship between the starting point at which the irradiation with the oblique light L is initiated and the arrival point of the oblique light L at the exposed surface 2a of the underfill film 2. In this case, the angle of which the amount of light becomes maximum may fall within the range of the incident angle α.

The wavelength of the oblique light L is not especially limited as long as the reflected image from the semiconductor wafer 3 can be obtained, and the irradiation is performed without damaging the semiconductor wafer 3; however, it is preferably 400 to 550 nm. If the wavelength of the oblique light L is in this range, the oblique light L can suitably transmit the underfill film 2, and therefore the dicing position can be easily detected.

In FIG. 2E and FIG. 3, the connection member (for example, a bump) 4 that is formed on the semiconductor wafer 3 is considered to be the recognition object in the semiconductor wafer 3 for detecting the position by oblique light irradiation. However, the recognition object is not limited to this, and an arbitrarily mark such as an alignment mark, a terminal, and a circuit pattern; or a structure can be used as a recognition object.

<Dicing Step>

In the dicing step, the semiconductor wafer 3 and the underfill film 2 are diced to form the semiconductor element 5 with the underfill film 2 as shown in FIG. 2F. The dicing is performed from the circuit surface 3a to which the underfill film 2 of the semiconductor wafer 3 is bonded using an ordinary method. An example includes a cutting method called full cut in which cutting is performed up to the dicing tape 11. The dicing apparatus that is used in this step is not especially limited, and a conventionally known apparatus can be used.

When the expansion of the dicing tape 11 is performed successively after the dicing step, the expansion can be performed by using a conventionally known expanding apparatus.

<Pickup Step>

In order to collect the semiconductor element 5 with the underfill film 2 that is adhered and fixed to the dicing tape 11, the semiconductor element 5 with the underfill film 2 is peeled from the dicing tape 11 (the semiconductor element 5 with the underfill film 2 is picked up) as shown in FIG. 2F.

The pickup method is not especially limited, and various types of conventionally known methods can be adopted.

When the pressure-sensitive adhesive layer 11b of the dicing tape 11 is ultraviolet-curable, the pickup is performed after irradiating the pressure-sensitive adhesive layer 11b with ultraviolet rays. This allows the adhesive strength of the pressure-sensitive adhesive layer 11b to the semiconductor element 5 to be decreased, and makes peeling of the semiconductor element 5 easy. As a result, the pickup can be performed without damaging the semiconductor element 5.

[Position Matching Step]

Next, in the position matching step, the exposed surface of the underfill film 2 of the semiconductor element 5 with the underfill film 2 is irradiated with the oblique light L to match the relative positions of the semiconductor element 5 and the adherend 6 with the scheduled connection positions. This allows the position of the semiconductor element 5 to be detected at high accuracy, and the matching of the semiconductor element 5 and the adherend 6 with the scheduled connection positions to be simply and effectively performed.

Specifically, the semiconductor element 5 with the underfill film 2 is arranged above the adherend 6 so that the surface on which the connection member 4 of the semiconductor element 5 is formed (corresponding to the circuit surface 3a of the semiconductor wafer 3) faces the adherend 6. Next, an imaging apparatus 31 and a ring lighting 32 are arranged between the semiconductor element 5 with the underfill film 2 and the adherend 6, and the exposed surface 2a of the underfill film 2 is irradiated with the oblique light L at a prescribed incident angle α from the ring lighting 32 to the semiconductor element 5 with the underfill film 2. The oblique light L enters the underfill film 2, and the light that is reflected at the semiconductor element 5 is received by the imaging apparatus 31 as a reflected image. Next, the reflected image that is received is analyzed with an image recognition apparatus, the deviation of the current position from the predetermined scheduled connection position is obtained, and finally the semiconductor element 5 with the underfill film 2 is moved by the amount of the obtained deviation to match the relative positions of the semiconductor element 5 and the adherend 6 with the scheduled connection positions (not shown in the figures).

The oblique light irradiation in this position matching step differs from the oblique light irradiation in the dicing position determination step only in terms that the positions of the exposed surface 2a of the underfill film 2 in relation to the imaging apparatus 31 and the lighting 32 are inverted. Therefore, the conditions that are described in the section of the dicing position determination step can be suitably adopted for the conditions for the oblique light irradiation such as lighting for the oblique light irradiation, a source of the lighting, a direction of the irradiation, a range of the incident angle α, a wavelength of the oblique light, and a recognition object in the semiconductor element for detecting the position by oblique light irradiation; and the same effect can be obtained.

<Connecting Step>

In the connecting step, the semiconductor element 5 and the adherend 6 are electrically connected to each other while filling the space between the adherend 6 and the semiconductor element 5 with the underfill film 2 (refer to FIG. 2I).

Specifically, the connection member 4 that is formed on the semiconductor element 5 is brought into contact with a conductive material 7 for bonding that is attached to the connection pad of the adherend 6, and the conductive material 7 is melted while pressing the connection member 4 to electrically connect the semiconductor element 5 and the adherend 6 to each other. Since the underfill film 2 is bonded to the surface on which the connection member 4 of the semiconductor element 5 is formed, the semiconductor element 5 and the adherend 6 are electrically connected to each other and the space between the semiconductor element 5 and the adherend 6 is filled with the underfill film 2.

The heating condition in the connecting step is not especially limited, and normally, the heating condition is 100 to 300° C., and the pressure application condition is 0.5 to 500 N.

<Curing Step>

After the semiconductor element 5 and the adherend 6 are electrically connected to each other, the underfill film 2 is cured under heating. This makes it possible to protect the surface of the semiconductor element 5, and to secure the connection reliability between the semiconductor element 5 and the adherend 6. The heating temperature for curing the underfill film 2 is not especially limited, and for example, it is 150 to 200° C. for 10 to 120 minutes. The underfill film 2 may be cured by the heating process in the connecting step.

<Sealing Step>

Next, a sealing step may be performed for protecting an entire semiconductor device 30 including the semiconductor element 5 mounted. The sealing step is performed by using a sealing resin. The sealing condition is not especially limited, and heating is normally performed at 175° C. for 60 seconds to 90 seconds to thermally cure the sealing resin. However, the present invention is not limited to this. For example, the curing can be performed at 165° C. to 185° C. for a few minutes.

A resin having an insulating property (an insulating resin) is preferable as the sealing resin, and the sealing resin can be appropriately selected from known sealing resins for use.

<Semiconductor Device>

In the semiconductor device 30, the semiconductor element 5 and the adherend 6 are electrically connected to each other through the connection member 4 that is formed on the semiconductor element 5 and the conductive material 7 that is provided on the adherend 6. The underfill film 2 is arranged between the semiconductor element and the adherend 6 so that it fills the space. Since the semiconductor device 30 can be obtained with a manufacturing method adopting the position matching by oblique light irradiation, a good electrical connection is achieved between the semiconductor element 5 and the adherend 6.

### Embodiment 2

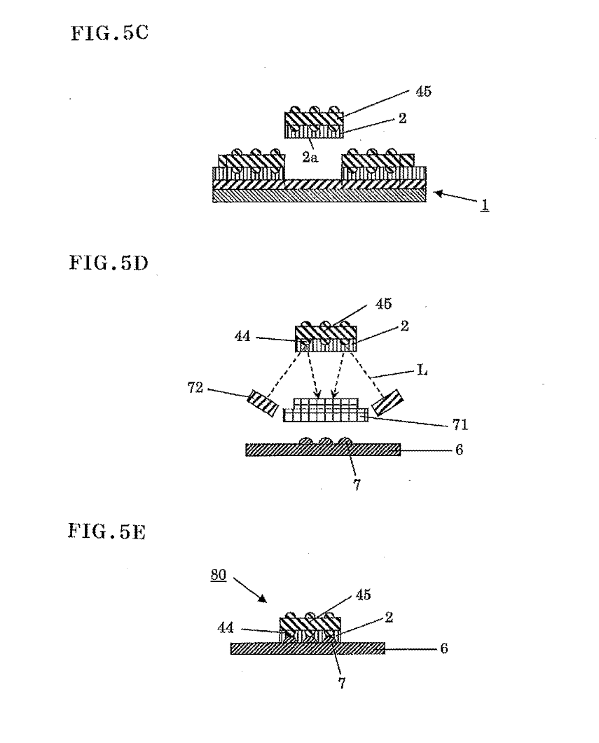

The method of manufacturing a semiconductor device of Embodiment 2 is explained. FIGS. 5A to 5E are views showing each step of the method of manufacturing a semiconductor device of Embodiment 2.

The sealing sheet 10 is used in Embodiment 2.

The method of manufacturing a semiconductor device of Embodiment 2 includes a bonding step of bonding a semiconductor wafer 43 on which a circuit surface having connection members 44 is formed on both surfaces and the underfill film 2 of the sealing sheet 10 together, a dicing step of dicing the semiconductor wafer 43 to form a semiconductor chip 45 with the underfill film 2, a pickup step of peeling the semiconductor chip 45 with the underfill film 2 from the pressure-sensitive adhesive tape 1, a position matching step of irradiating the exposed surface of the underfill film 2 of the semiconductor element 45 with the underfill film 2 with the oblique light L to match the relative positions of the semiconductor element 45 and the adherend 6 with the scheduled connection positions, a connecting step of electrically connecting the adherend 6 and the semiconductor element 45 with the underfill film 2 while filling the space between the adherend 6 and the semiconductor element 45 with the underfill film 2 of the semiconductor element 45 with the underfill film 2.

<Bonding Step>

In the bonding step, the semiconductor wafer 43 on which a circuit surface having the connection members 44 is formed on both surfaces and the underfill film 2 of the sealing sheet 10 are bonded together as shown in FIG. 5A. Since the strength of the semiconductor wafer 43 is normally weak, the semiconductor wafer 43 may be fixed to a support such as a support glass for reinforcement (not shown in the figures). In this case, the manufacturing method may include a step of peeling the support after the semiconductor wafer 43 and the underfill film 2 are bonded together. When anyone of the circuit surfaces of the semiconductor wafer 43 is bonded to the underfill film 2, the combination to be bonded may be changed according to a structure of the targeted semiconductor device.

The connection members 44 on both surfaces of the semiconductor wafer 43 may be or may not be electrically connected to each other. An example of the electrical connection of the connection members 44 includes a connection through a via hole called a TSV method. The same condition that is explained in the bonding step of Embodiment 1 can be adopted as the bonding conditions.

<Dicing Step>

In the dicing step, the semiconductor wafer 43 and the underfill film 2 are diced to form the semiconductor chip 45 with the underfill film 2 (refer to FIG. 45). The same conditions that are explained in the dicing step of Embodiment 1 can be adopted as the dicing conditions.

<Pickup Step>

In the pickup step, the semiconductor chip 45 with the underfill film. 2 is peeled from the pressure-sensitive adhesive tape 1 (FIG. 5C). The same conditions that are explained in the pickup step of Embodiment 1 can be adopted as the pickup step.

<Position Matching Step>

The exposed surface of the underfill film 2 of the semiconductor element 45 with the underfill film 2 is irradiated with the oblique light L to match the relative position of the semiconductor element 45 to the adherend 6 with the scheduled connection position (FIG. 5D). The same method as in Embodiment 1 can be adopted as the specific position matching method.

<Connecting Step>

In the connecting step, the adherend 6 and the semiconductor element 45 with the underfill film 2 are electrically connected while filling the space between the adherend 6 and the semiconductor element 45. The same method that is explained in the connecting step of Embodiment 1 can be adopted as the specific connecting method.

<Curing Step and Sealing Step>

The curing step and the sealing step are the same ones as the content that is explained in the curing step and the sealing step of Embodiment 1. This allows a semiconductor device 80 to be manufactured.

### Embodiment 3

The method of manufacturing a semiconductor device of Embodiment 3 is explained. Embodiment 3 is the same one as Embodiment 1 except that the underfill film is provided on the base. The same base as the base 1a can be used as the base.

### Examples

The preferred working examples of this invention will be explained in detail below. However, the materials, the compounding amounts, etc., described in the working examples are not intended to be limited thereto in the scope of this invention unless otherwise specified.

Each component that was used in the Examples and Comparative Examples was explained together.

Acrylic resin: Acrylic acid ester polymer containing ethylacrylate-methylmethacrylate as main component (trade name “Paracron W-197CM” manufactured by Negami Chemical Industrial Co., Ltd.)

Epoxy resin 1: trade name “Epikote 1004” manufactured by JER Corporation

Epoxy resin 2: trade name “Epikote 828” manufactured by JER Corporation

Phenol resin: trade name “Milex XLC-4L” manufactured by Mitsui Chemicals, Inc.

Alumina filler 1: trade name “ALMEK30WT %-N40” manufactured by CIK NanoTek Corporation (average particle size 0.35 μm, maximum particle size 3.0 μm, thermal conductivity 40 W/mK)

Alumina filler 2: trade name “AS-50” manufactured by SHOWA DENKO K.K. (average particle size 9.3 μm, maximum particle size 30 μm, thermal conductivity 41 W/mK)

Alumina filler 3: trade name “DAW-07” manufactured by DENKI KAGAKU KOGYO KABUSHIKI KAISHA (average particle size 8.2 μm, maximum particle size 27 μm, thermal conductivity 40 W/mK)

Alumina filler 4: trade name “DAW-05” manufactured by DENKI KAGAKU KOGYO KABUSHIKI KAISHA (average particle size 5.1 μm, maximum particle size 18 μm, thermal conductivity 40 W/mK)

Organic acid: trade name “Ortho-Anisic Acid” manufactured by Tokyo Chemical Industry Co., Ltd.

Imidazole catalyst: trade name “2PHZ-PW” manufactured by SHIKOKU CHEMICALS CORPORATION (2-phenyl-4,5-dihydroxymethylimidazole)

### Examples 1 and 2 and Comparative Examples 1 to 3

### Production of Underfill Film

Each of the components was dissolved in methylethylketone at the proportions shown in Table 1 to prepare solutions of adhesive compositions each of which has a solid concentration of 23.6% by weight.

Each of the solutions of the adhesive compositions was applied onto a release-treated film of a silicone release treated polyethylene terephthalate film having a thickness of 50 μm, and the resultant was dried at 130° C. for 2 minutes to produce an underfill film having a thickness of 30 μm.

The following evaluations were performed on the obtained underfill film. The results are shown in Table 1.

### Arithmetic Average Roughness (Ra)

The arithmetic average roughness (Ra) of the underfill film was measured using a non-contact three-dimensional profilometer (NT3300) manufactured by Veeco Instruments, Inc. based on JIS B 0601. The measurement condition is set to 50 magnifications, and a median filter is used to the measurement data to obtain a measurement value. The measurement was performed 5 times while changing the measurement point, and the average value was obtained to be the arithmetic average roughness (Ra).

### Thermal Conductivity

The underfill film was thermally cured by heating treatment at 175° C. for 1 hour in a dryer. Thereafter, the thermal diffusivity α (m²/s) of the underfill film was measured with a TWA (Temperature Wave Analysis) method (measurement apparatus “ai-Phase Mobile” manufactured by ai-Phase Co., Ltd.) Next, the specific heat Cₚ (J/g·° C.) of the underfill film was measured with a DSC method. The measurement of the specific heat was performed using “DSC6220” manufactured by SII Nano Technology Inc. under the conditions of a rising temperature speed of 10° C./min and a temperature range of 20 to 300° C., and the specific heat was calculated based on the obtained experimental data using the JIS handbook (method of measuring a specific heat capacity K-7123). The specific gravity of the underfill film was also measured.

The thermal conductivity was calculated using the following formula based on the thermal diffusivity α, the specific heat Cₚ, and the specific gravity. The results are shown in Table 1.

Thermal Conductivity (W/m·K)=Thermal Diffusivity (m²/s)×Specific Heat (J/g·° C.)×Specific Gravity (g/cm³) [Formula 1]

### Filling Property

(1) Production of Underfill Film Integrated with Dicing Tape

The underfill film was bonded on the pressure-sensitive adhesive layer of a dicing tape (trade name “V-8-T” manufactured by NITTO DENKO CORPORATION) using a hand roller to produce an underfill film integrated with a dicing tape.

(2) Production of Semiconductor Device

A silicon wafer with a bump on one side was prepared in which a bump was formed on one side of the wafer. The underfill film integrated with a dicing tape was bonded to the surface of the silicon wafer with a bump on one side where the bumps were formed by using the underfill film as the bonding surface. The following silicon wafer was used as the silicon wafer with a bump on one side. The bonding conditions are as follows. The ratio (Y/X) of the thickness Y (=30 μm) of the underfill material to the height X (=35 μm) of the connection member was 0.86.

Silicon wafer with a bump on one surface

Diameter of silicon wafer: 8 inches

Thickness of silicon wafer: 0.2 mm (thickness after grinding the rear surface of a wafer having a thickness of 0.7 mm using a grinding apparatus “DFG-8560” manufactured by DISCO Corporation)

Height of bump: 35 μm

Pitch of bump: 50 μm

Material of bump: SnAg solder+Copper pillar

### Bonding Conditions

Bonding apparatus: trade name “DSA840-WS” manufactured by NITTO SEIKI CO., LTD.

Bonding speed: 5 mm/min

Bonding pressure: 0.25 MPa

Stage temperature at bonding: 80° C.

Degree of reduced pressure at bonding: 150 Pa

After bonding, the silicon wafer was diced with the following conditions. The dicing was performed in full cut so that the chip size became 7.3 mm square.

### Dicing Conditions

Dicing apparatus: trade name “DFD-6361” manufactured by DISCO Corporation

Dicing ring: trade name “2-8-1” manufactured by DISCO Corporation

Dicing speed: 30 mm/sec

Dicing blades:
Z1; trade name “2030-SE 27HCDD” manufactured by DISCO Corporation
Z2; trade name “2030-SE 27HCBB” manufactured by DISCO Corporation

Rotations of the dicing blades:
Z1; 40,000 rpm
Z2; 40,000 rpm

Cutting method: Step cut

Size of the wafer chip: 7.3 mm square

Next, the laminate of the underfill film and the semiconductor chip with a bump on one side (semiconductor chip with an underfill film) was picked up with a pushing-up method by a needle from the base side of each dicing tape.

The exposed surface of the underfill film was irradiated with oblique light with an incident angle α of 45° to match the position, and the semiconductor chip was mounted to a BGA substrate with the bump formation surface of the semiconductor chip facing to the BGA substrate at the scheduled connection position. This provided a semiconductor device in which the semiconductor chip was mounted to the BGA substrate. In this mounting step, a two-stage processing was performed in which a process with the mounting conditions 2 was performed successively to a process with the mounting conditions 1.

### Mounting Conditions 1

Pickup apparatus: trade name “FCB-3” manufactured by Panasonic Corporation

Heating temperature: 150° C.

Load: 10 kg

Holding time: 10 seconds

### Mounting Conditions 2

Pickup apparatus: trade name “FCB-3” manufactured by Panasonic Corporation

Heating temperature: 260° C.

Load: 10 kg

Holding time: 10 seconds

(3) Evaluation of Filling Property

The obtained semiconductor device was polished until the connection terminals appeared on the surface that is parallel to the chip. The parallel cross section was observed with a microscope, and the case in which the area of voids was 5% or less of the area of the cross section was evaluated as ∘, and the case in which the area of voids exceeded 5% was evaluated as x.

TABLE 1
Thickness of Underfill Film 30 μm

| | | | | Comparative | Comparative | Comparative |
|---|---|---|---|---|---|---|
| | | Example 1 | Example 2 | Example 1 | Example 2 | Example 3 |
| Compounding | Acrylic Resin | 100 | 100 | 100 | 100 | 100 |
| (parts by | Epoxy Resin 1 | 56 | 56 | 56 | 56 | 56 |
| weight) | Epoxy Resin 2 | 19 | 19 | 19 | 19 | 19 |
| | Phenol Resin | 75 | 75 | 75 | 75 | 75 |
| | Alumina Filler 1 | 580 | 1410 | — | — | 250 |
| | Alumina Filler 2 | — | — | 580 | — | — |
| | Alumina Filler 3 | — | — | — | 580 | — |
| | Organic Acid | 1.3 | 1.3 | 1.3 | 1.3 | 1.3 |
| | Imidazole Catalyst | 1.3 | 1.3 | 1.3 | 1.3 | 1.3 |
| Average Particle Size (%) of Alumina Filler to | | 1.2 | 1.2 | 31.0 | 27.3 | 1.2 |
| Thickness of Film | | | | | | |
| Maximum Particle Size (%) of Alumina Filler to | | 10 | 10 | 100 | 90 | 10 |
| Thickness of Film | | | | | | |
| Content (% by volume) of Alumina Filler | | 50 | 70 | 50 | 50 | 36 |
| Evaluation | Arithmetic Average Roughness (nm) | 170 | 230 | 460 | 350 | 150 |
| | Thermal Conductivity (W/mK) | 2.3 | 3.2 | 2.2 | 2.3 | 1.1 |
| | Filling Property | ○ | ○ | × | × | ○ |

### Examples 3 and 4 and Comparative Example 4

Each of the underfill films was produced with the same method as in Example 1 except that the proportions of the components shown in Table 2 were used and the thickness of the underfill film was 10 μm.

The arithmetic average roughness and the thermal conductivity of each of the obtained underfill films were evaluated with the same methods as in Example 1. The filling property was evaluated with the same method as in Example 1 except that a silicon wafer with a bump on one side was used with the height of bump being 12 μm. The results are shown in Table 2.

TABLE 2
Thickness of Underfill Film 10 μm

| | | | | Compar- |
|---|---|---|---|---|
| | | Exam- | Exam- | ative |
| | | ple 3 | ple 4 | Example 4 |
| Compounding | Acrylic Resin | 100 | 100 | 100 |
| (parts by | Epoxy Resin 1 | 56 | 56 | 56 |
| weight) | Epoxy Resin 2 | 19 | 19 | 19 |
| | Phenol Resin | 75 | 75 | 75 |
| | Alumina Filler 1 | 580 | 1410 | — |
| | Alumina Filler 4 | — | — | 580 |
| | Organic Acid | 1.3 | 1.3 | 1.3 |
| | Imidazole Catalyst | 1.3 | 1.3 | 1.3 |
| Average Particle Size (%) of Alumina | | 3.5 | 3.5 | 51.0 |
| Filler to Thickness of Film | | | | |
| Maximum Particle Size (%) of Alumina | | 30 | 30 | 180 |
| Filler to Thickness of Film | | | | |
| Content (% by volume) of Alumina Filler | | 50 | 70 | 50 |
| Evaluation | Arithmetic Average | 170 | 230 | 330 |
| | Roughness (nm) | | | |
| | Thermal Conduc- | 2.3 | 3.2 | 2.4 |
| | tivity (W/mK) | | | |
| | Filling Property | ∘ | ∘ | x |

### REFERENCE CHARACTER LIST

1 Pressure-Sensitive Adhesive Tape
1a Base
1b Pressure-Sensitive Adhesive Layer
2 Underfill Film
2a Exposed Surface of Underfill Film
3, 43 Semiconductor Wafer
3a Circuit Surface of Semiconductor Wafer
3b Surface opposite to Circuit Surface of Semiconductor Wafer
4, 44 Connection Member
5, 45 Semiconductor Element (Semiconductor Chip)
6 Adherend
7 Conductive Material
10 Sealing sheet
11 Dicing Tape
11a Base
11b Pressure-Sensitive Adhesive Layer
21, 31, 71 Imaging Apparatus
22, 32, 72 Ring Lighting
30, 80 Semiconductor Device
L Oblique Light
α Incident Angle of Oblique Light

1. An underfill film comprising:
a resin; and
a thermally conductive filler;
wherein a content of the thermally conductive filler is 50% by volume or more;
wherein an average particle size of the thermally conductive filler is 30% or less of a thickness of the underfill film; and
wherein a maximum particle size of the thermally conductive filler is 80% or less of the thickness of the underfill film.

2. The underfill film according to claim 1, wherein a thermal conductivity is 2 W/mK or more.

3. The underfill film according to claim 1, wherein the content of the thermally conductive filler is 50% to 80% by volume;
wherein the average particle size of the thermally conductive filler is 10 to 30% of the thickness of the underfill film; and
wherein the maximum particle size of the thermally conductive filler is 40 to 80% of the thickness of the underfill film.

4. The underfill film according to claim 1, wherein an arithmetic average roughness (Ra) is 300 nm or less.

5. The underfill film according to claim 1, wherein the thermally conductive filler has a multimodal particle size distribution indicating presence of at least two filler components having mutually different average particle sizes.

6. The underfill film according to claim 1, wherein a total light transmittance is 50% or more.

7. A sealing sheet comprising:
the underfill film according to claim 1; and
a pressure-sensitive adhesive tape;
wherein the pressure-sensitive adhesive tape has a base and a pressure-sensitive adhesive layer that is provided on the base; and
wherein the underfill film is provided on the pressure-sensitive adhesive layer.

8. The sealing sheet according to claim 7, wherein a peel strength of the underfill film from the pressure-sensitive adhesive layer is 0.03 to 0.10 N/20 mm.

9. The sealing sheet according to claim 7, wherein the pressure-sensitive adhesive tape is a tape for grinding the rear surface of a semiconductor wafer or a dicing tape.

10. A method of manufacturing a semiconductor device, the method comprising:
preparing an element-film composite in which the underfill film according to claim 1 is bonded to a semiconductor element; and
electrically connecting an adherend and the semiconductor element while filling the space between the adherend and the semiconductor element with the underfill film.

11. The method of manufacturing a semiconductor device according to claim 10, further comprising:
irradiating an exposed surface of the underfill film of the semiconductor element with oblique light; and
causing relative positions of the semiconductor element and the adherend to become aligned with respective connection positions.

12. The method of manufacturing a semiconductor device according to claim 11, wherein the exposed surface is irradiated with the oblique light at an incident angle of 5 to 85°.

13. The method of manufacturing a semiconductor device according to claim 11, wherein the oblique light contains a wavelength of 400 to 550 nm.

14. The method of manufacturing a semiconductor device according to claim 11, wherein the exposed surface of the underfill film is irradiated with the oblique light from two or more directions or all directions.

15. A semiconductor device manufactured by using the underfill film according to claim 1.

16. A semiconductor device manufactured with the method according to claim 10.
